(19) United States
(12) Patent Application Publication
(10) Pub. No.: US 2025/0192090 A1
(43) Pub. Date: Jun. 12, 2025

(54) SEMICONDUCTOR DEVICES WITH SIDEWALL RECESSES

(71) Applicant: SEMICONDUCTOR COMPONENTS INDUSTRIES, LLC, Scottsdale, AZ (US)

(72) Inventors: Rennier RODRIGUEZ, Calamba City (PH); John Alexander SORIANO, Cabuyao City (PH); Jorell Dulay PELINGO, Marikina (PH)

(73) Assignee: SEMICONDUCTOR COMPONENTS INDUSTRIES, LLC, Scottsdale, AZ (US)

(21) Appl. No.: 18/534,065

(22) Filed: Dec. 8, 2023

(51) Int. Cl. H01L 23/00; H01L 21/8234; H01L 23/495

(52) U.S. Cl. CPC H01L 24/32; H01L 24/29; H10D 84/0149; H10D 84/038; H01L 23/49586; H01L 24/48; H01L 24/73; H01L 2224/26145; H01L 2224/2919; H01L 2224/2957; H01L 2224/32013; H01L 2224/32059; H01L 2224/32245; H01L 2224/48245; H01L 2224/73265; H01L 2924/182

(57) ABSTRACT

Implementations of a semiconductor device may include a first surface having a first perimeter; and a second surface opposite the first surface, the second surface having a second perimeter, the first perimeter being greater than the second perimeter. The semiconductor device may include a sidewall extending between the first surface and the second surface, the sidewall defining an overhang where a width of the overhang extends between the first perimeter and the second perimeter, and a thickness of the overhang is less than a thickness of the semiconductor device. The overhang may be configured to keep epoxy away from the first side.

### BACKGROUND

### 1. Technical Field

Aspects of this document relate generally to semiconductor devices and methods of manufacturing thereof. More specific implementations involve a recess or overhang formed in a sidewall of the semiconductor device.

### 2. Background

Semiconductor devices include integrated circuits found in common electrical and electronic devices, such as phones, desktops, tablets, other computing devices, and other electronic devices. During fabrication, wafers are singulated into die. The die are then packaged to allow them to communication with a motherboard or other circuit board to which the package is coupled.

### SUMMARY

Implementations of a semiconductor device may include a first surface having a first perimeter; and a second surface opposite the first surface, the second surface having a second perimeter, the first perimeter being greater than the second perimeter. The semiconductor device may include a sidewall extending between the first surface and the second surface, the sidewall defining an overhang where a width of the overhang extends between the first perimeter and the second perimeter, and a thickness of the overhang is less than a thickness of the semiconductor device. The overhang may be configured to keep epoxy away from the first side.

Implementations of a semiconductor device may include one, all, or any of the following:

The sidewall may be curved or rounded.

The sidewall may be angular.

The sidewall may include a bevel.

The sidewall may be mechanically cut or laser cut

The thickness of the semiconductor device may be between 50 microns to 150 microns.

The thickness of the overhang may be 50% of the semiconductor device thickness.

Implementations of a method of singulating a plurality of die from a semiconductor substrate may include cutting a recess into a bottom region of a die, the recess having a first width along a bottom surface of the die, and the recess having at least one beveled edge. The method may also include singulating the die at the recess using a kerf width of a second width where the second width may be smaller than the first width.

Implementations of a method of singulating a plurality of die from a semiconductor substrate may include one, all, or any of the following:

The recess may be configured to prevent epoxy flowing onto a top surface of die.

The sidewall may extend between a top surface of the die and a bottom surface of the die, the sidewall defining an overhang adjacent the recess. A thickness of the overhang may be less than a thickness of the die and the overhang configured to prevent epoxy flow onto the top surface of the die.

The thickness of the overhang may be 50% of the thickness of the die.

The thickness of the die may be between 50 microns to 150 microns.

The recess may be mechanically cut.

Implementations of a method of singulating a plurality of die from a semiconductor substrate may include forming a recess in a backside layer applied to a backside of a semiconductor substrate using a stencil, the recess having a first width along a first surface of the backside layer; and forming a plurality of die by singulating the semiconductor substrate in the recess using a kerf width of a second width. The second width may be smaller than the first width.

Implementations of a method of singulating a plurality of die from a semiconductor substrate may include one, all, or any of the following:

The first surface of the backside layer may be adjacent to the backside of the semiconductor substrate.

The backside layer may include epoxy, glue, a die bonding material, or any combination thereof.

The backside layer may include only a carbon-containing material.

The sidewall may extend between the backside surface of the semiconductor substrate and the first surface of the backside layer and a face of the backside surface of the semiconductor substrate may extend past the first surface of the backside layer.

The second width may be 50% of a thickness of the semiconductor device.

The thickness of the semiconductor substrate may be from 50 microns to 150 microns.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a cross sectional side view of an implementation of a semiconductor device coupled to a substrate via an adhesive;

FIG. 2 is a partial view of the implementation of the semiconductor device and substrate of FIG. 1;

FIG. 3 is a partial view of the semiconductor device of FIG. 1;

FIG. 4 is a cross sectional side view of an implementation of a semiconductor substrate;

FIG. 5 is a cross sectional side view of the semiconductor substrate of FIG. 4 coupled to a mask layer;

FIG. 6 is a cross sectional side view of the semiconductor substrate of FIG. 5 after etching;

FIG. 7 is a cross sectional side view of the semiconductor substrate of FIG. 6 after the mask layer has been removed;

FIG. 8 is a cross sectional side view of the semiconductor substrate of FIG. 7 coupled to a metal layer;

FIG. 9 is a cross sectional side view of the semiconductor substrate of FIG. 8 after singulating;

FIG. 10 is a cross sectional side view of an implementation of a semiconductor substrate mounted top-down on a cutting tape;

FIG. 11 is a cross sectional side view of the semiconductor substrate of FIG. 10 with a recess cut therein;

FIG. 12 is a cross sectional side view of the semiconductor substrate of FIG. 11 with a metal layer coupled to a backside thereof;

FIG. 13 is a cross sectional side view of the semiconductor substrate of FIG. 12 after singulating;

FIG. 14 is a bottom view of the semiconductor device of FIG. 13;

FIG. 15 is a cross sectional side view of an implementation of a semiconductor substrate mounted top-down on a cutting tape;

FIG. 16 is a cross sectional side view of the semiconductor substrate of FIG. 15 with a beveled recess cut therein;

FIG. 17 is a cross sectional side view of the semiconductor substrate of FIG. 16 with a metal layer coupled to a backside thereof;

FIG. 18 is a cross sectional side view of the semiconductor substrate of FIG. 17 following singulating;

FIG. 19 is a bottom view of the semiconductor device of FIG. 15;

FIG. 20 is a cross sectional side view of an implementation of a semiconductor substrate mounted top-down on a cutting tape;

FIG. 21 is a cross sectional side view of the semiconductor substrate of FIG. 20 with a laser cut recess therein;

FIG. 22 is a cross sectional side view of the semiconductor substrate of FIG. 21 with a metal layer coupled to a backside thereof;

FIG. 23 is a cross sectional side view of the semiconductor substrate of FIG. 22 after singulating;

FIG. 24 is a bottom view of the semiconductor substrate of FIG. 23;

FIG. 25 is a cross sectional side view of an implementation of a semiconductor substrate having a metal layer deposited thereon;

FIG. 26 is a cross sectional side view of an implementation of a semiconductor substrate mounted active side-down on a cutting tape;

FIG. 27 is a cross sectional side view of the semiconductor substrate of FIG. 26 coupled to a printed layer; and

FIG. 28 is a cross sectional side view of the semiconductor substrate of FIG. 27 after singulating.

This disclosure, its aspects and implementations, are not limited to the specific components, assembly procedures or method elements disclosed herein. Many additional components, assembly procedures and/or method elements known in the art consistent with the intended semiconductor devices and systems and methods thereof will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such semiconductor devices and systems and methods thereof, and implementing components and methods, consistent with the intended operation and methods.

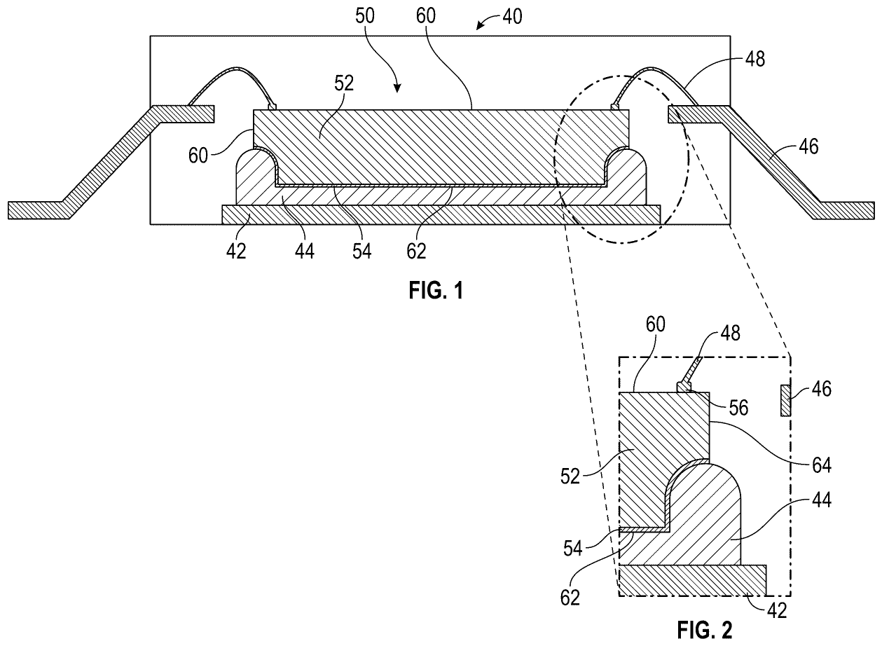

Referring to FIGS. 1 and 2, cross sectional side views of an implementation of a semiconductor package are illustrated. The semiconductor package 40 includes a die 50 attached to a package substrate/leadframe 42 via an epoxy or adhesive 44. Leads 46 are connected to die 50 at pads 56 via bonding wires 48 which electrically connect die 50 to desired external elements like a circuit board or other motherboard to which the semiconductor package 40 is attached. Die 50 may be any type of semiconductor die including, by non-limiting example, a diode, a vertical transistor, a lateral transistor, an insulated gate bipolar transistor (IGBT), a metal oxide field effect transistor (MOSFET), a high-electron-mobility transistor (HEMT), a power semiconductor device, an integrated circuit, or any other semiconductor die type. A die, in the context of integrated circuits, is a small block of semiconducting material on which a given functional circuit or semiconductor device is fabricated. Die 50 includes a portion of a semiconductor substrate 52 that may have doped regions formed within the substrate to form active and passive regions of the die 50 depending upon the type of semiconductor device(s) formed in the die 50.

The term “substrate” refers to a semiconductor substrate as a semiconductor substrate is a common type of substrate, however, “substrate” is not an exclusive term that is used to refer to all semiconductor substrate types. Similarly, the term “substrate,” may refer to a wafer as a wafer is a common type of substrate, however, “substrate” is not an exclusive term that is used to refer to all wafers. The various semiconductor substrate types disclosed in this document that may be utilized in various implementations may be, by non-limiting example, round, rounded, square, rectangular, or any other closed shape. In various implementations, the substrate 52 may include a substrate material such as, by non-limiting example, single crystal silicon, silicon dioxide, glass, gallium arsenide, sapphire, ruby, silicon on insulator, silicon carbide, polycrystalline or amorphous forms of any of the foregoing, and any other substrate material useful for constructing semiconductor devices. In various implementations, the substrate 52 is thinned. In particular implementations, the substrate 52 may be less than about 50 micrometers (μm) thick, about 50 μm to about 150 μm thick, and/or greater than about 150 μm thick to a thickness less than the ordinary fabrication processing thickness. In other implementations, the substrate 52 may not be thinned but may be processed at the standard fabrication processing thickness used in fab.

As illustrated in FIG. 1, die 50 may include an additional layer 54 coupled to die substrate 52. In various implementations, the additional layer 54 is a metal layer or metal alloy layer coupled to substrate 52. In other implementations, however, the additional layer 54 may not be included, or may include more than one layer of material.

In the implementation illustrated in FIGS. 1 and 2, die 50 is coupled to a packaging substrate 42 via an epoxy 44 during a die attach process. Epoxy die attach is a bonding process that utilizes one or more epoxy resins as a connecting adhesive to physically couple the die 50 to the substrate/leadframe/die flag 52. The epoxy 44 may be in various implementations, by non-limiting example, an epoxy, a glue, a die bonding material, an adhesive, a die attach film, any combination thereof, or any other polymer, filler, colorant, or reinforcing agent included therein. As illustrated in FIGS. 1 and 2, die 50 includes a top/active surface 60, a bottom surface 62 and sidewalls 64 on the left and right sides of die 50 as illustrated in cross section.

During the die attach process, the die is placed on top of epoxy already deposited onto the packaging substrate. Epoxy fillet height refers to a build-up of epoxy on the die sidewalls after the die is placed on the packaging substrate. Generally, epoxy fillet height is targeted to be a maximum of 75% of the total die thickness. As the thickness of the die becomes thinner, maintaining a target fillet height becomes challenging as is preventing flow of epoxy onto the top surface of the die. As illustrated in FIGS. 1 and 2 sidewalls 64 are configured to prevent epoxy 44 from flowing onto the top surface 60 of die 50.

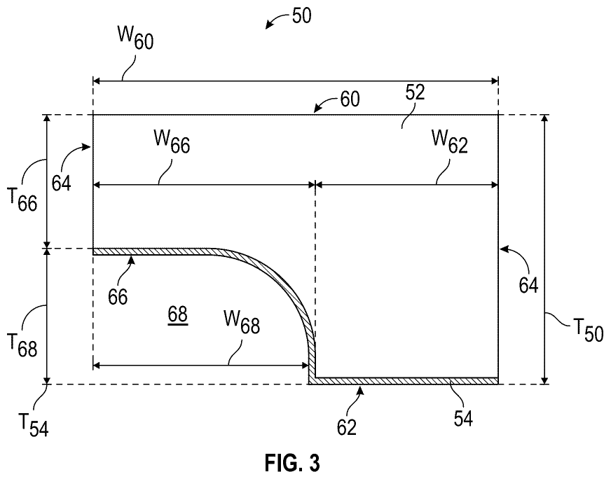

FIG. 3 illustrates a detail view of the sidewall area of die 50 without the epoxy 44 present. As illustrated, die 50 has a total die thickness T₅₀. Sidewall 64 extends between a top/active surface 60 and a bottom surface 62 and defines/includes an overhang 66 and a recess 68. Sidewall 64 is structured such that a lower portion of the sidewall adjacent bottom surface 62 is recessed into substrate 52 thus forming overhang 66 above recess 68. A thickness of the overhang T₆₆ is about 50% or more of the total die thickness T₅₀ and a thickness of the recess T₆₈ is about 50% or less of the total die thickness T₅₀. In some implementations, the range of thicknesses for T₆₆ and T₆₈ may be between about 25 microns to 75 microns. The total die thickness T₅₀ thus includes the overhang thickness T₆₆, recess thickness T₆₈, and a thickness T₅₄ of metal layer 54 (if the layer 54 is included in the particular implementation). The total die thickness T₅₀ may range from about 50 to about 150 micrometers. As illustrated, the recess 68 has a width W₆₈. A width of the recess W₆₈, and, in this implementation, a width W₆₆ of overhang 66, is the difference between a width W₆₀ of the top surface 60 and a width W₆₂ of the bottom surface 62. As illustrated in FIGS. 1-3, sidewall 64 is configured to keep epoxy 44 away from the top surface 60 of die 50. The epoxy 44 is able to flow into and occupy a volume formed by the recess 68, and thus, sidewall 64 and recess 68 are configured to prevent epoxy from flowing onto the top surface 60 of die 50. Consequently, the epoxy fillet height may also be maintained below 75% of the total die thickness T₅₀ and at 50% or less of the total die thickness T₅₀.

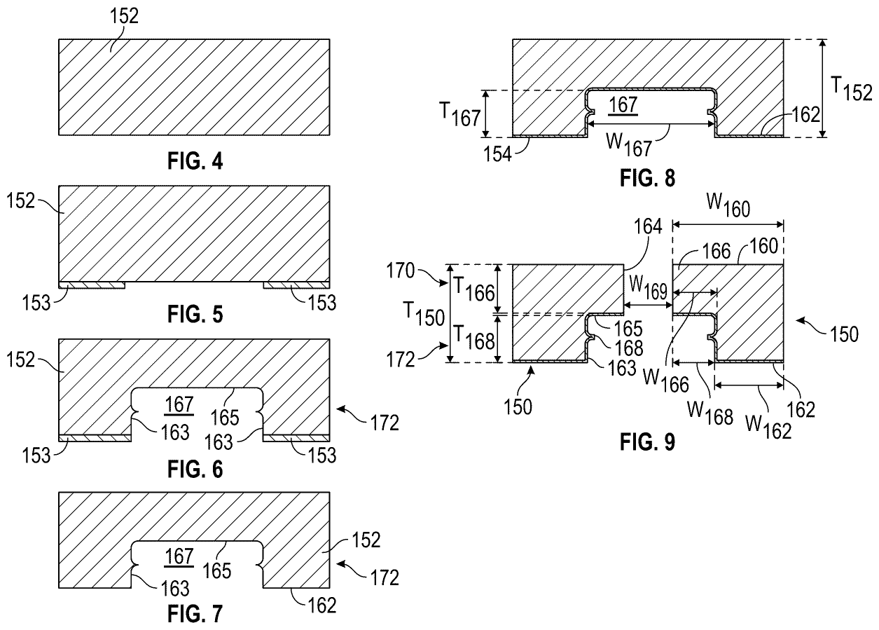

FIGS. 4-9 illustrate a semiconductor substrate at various points during an implementation of a of method of singulating a semiconductor substrate. FIG. 4 illustrates an implementation of a semiconductor substrate 152. The substrate 152 may be the same as or similar to any substrate type disclosed herein. In various implementations, a method of singulating a plurality of die included in a substrate includes singulating a plurality of die included in the substrate 152 through etching and/or mechanical cutting. In various implementations, a plasma etch process marketed under the tradename BOSCH® by Robert Bosch GmbH, Stuttgart, Germany (the “Bosch process”), may be used to create a recess in the substrate material and/or singulate the substrate material. In other method implementations disclosed herein, a saw, laser, water jet, or scribe and break processes may be used to form a recess and/or to singulate the plurality of die from the substrate.

Referring now to FIG. 5, a photoresist layer 153 is illustrated after having been applied and patterned to a bottom surface of substrate 152. As illustrated, the photoresist layer 153 is applied in areas where etching of substrate 152 is not desired. During imaging, the photoresist layer 153 (in the case of a positive photoresist) is exposed to electromagnetic radiation, for example, UV light, to cause chemical reactions in the exposed regions of the bottom surface of substrate 152 that will cause the photoresist material to wash away in the locations where a recess in a bottom region of substrate 152 is desired. In some implementations, the substrate 152 then undergoes a post exposure baking process before the exposed photoresist material 153 is removed using a development process. The development process involves treating the photoresist layer 153 with chemicals that promote chemical reactions where the exposed parts of substrate 152 are dissolved and carried away in a rinse process leaving an opening where the recess 167 ie is desired.

As illustrated in FIG. 6, a recess 167 is formed in the exposed/non-photoresist covered area of a bottom region 172 of substrate 152 following the patterning process. The photoresist layer 153 serves as a physical mask that protects areas of the bottom region 172 of substrate 152 from chemical attack during subsequent etching.

FIG. 7 illustrates the substrate 152 after etching using any etching method disclosed herein, including plasma etching. wet etching or dry etching, and after the photoresist layer 153 has been removed using, by non-limiting example, ashing, solvent stripping, or any combination thereof. As a result of the etching, a recess 167 is formed in the bottom region 172 of substrate 152. The recess is defined by horizontal surface 165 and lateral surfaces 163. While the formation of a single recess is illustrated in FIG. 6 and in the other method implementations disclosed herein, it must be understood that this process is repeated and carried out across the semiconductor substrate at desired locations adjacent to the die streets between the various semiconductor die.

FIG. 8 illustrates the substrate 152 after formation of an optional, additional layer 154 coupled to substrate 152. In various method implementations, the layer 154 may be a metal or metal alloy deposited onto substrate 152 and may include one or more layers. In various method implementations, the layer 154 is deposited on a bottom surface 162 of substrate 152 using various methods including, by non-limiting example, sputtering, evaporation, chemical vapor deposition, electroplating, electroless plating, or any other method of depositing the particular material of the layer 154. As illustrated in FIG. 8, recess 167 has a width W₁₆₇ and a thickness T₁₆₇ after metal layer 154 is added to substrate 152.

Referring to FIG. 9, a cross sectional side view of the substrate of FIG. 4 following singulation into semiconductor die 150 is illustrated. The various method implementations for singulating a plurality of die 150 included in the substrate 152 may include singulating the plurality of die 150 using any plasma etching, mechanical cutting or laser cutting and/or any other singulating method disclosed herein (laser/plasma etch/water jet cutting/scribing and breaking). As illustrated in FIGS. 8 and 9, this implementation uses sawing, and so the recess width W₁₆₇ is intentionally wider than a kerf width W₁₆₉ of the saw blade used so the etched recess width W₁₆₇ is wider than the width needed to singulate the die via sawing. By etching a wider area than needed for the singulating process, a recess 168 remains in each die 150 after singulating is performed as illustrated in FIG. 9.

During singulation, the saw blade cuts through kerf region 169 of substrate 162 adjacent recess 167 to singulate substrate 152 into die 150. As illustrated, die 150 includes a top surface 160, a bottom surface 162 and a sidewall 164 that extends between top surface 160 and bottom surface 162. Sidewall 164 includes a portion of horizontal surface 165 and the lateral surface 163 created during the formation of recess 167 (see FIG. 6). As illustrated, a top portion of sidewall 164 and horizontal surface 165 define an overhang 166 adjacent recess 168. The overhang 166 and recess 168 are formed due to the difference in width between the kerf width W₁₆₉ and the recess width W₁₆₇ during the singulation process. Since the kerf width W 169 is less than the recess width W₁₆₇, the resulting die 150 have a recess 168 in the bottom region 172 of die 150 and an overhang 166 in the top region 170 of die 150 adjacent recess 168. Lateral surface 163 is set into the material of substrate 152 by a width W₁₆₈ of recess 168.

As illustrated in FIG. 9, die 150 has a total die thickness T₁₅₀. A thickness T₁₆₆ of the overhang 166 is about 50% or more of the total die thickness T₁₅₀ and a thickness T₁₆₈ of the recess 168 is about 50% or less of the total die thickness T₁₅₀. The total die thickness T₁₅₀ includes the overhang thickness T₁₆₆, recess thickness T₁₆₈ and, where the layer 154 is present, the thickness T₁₅₄ of metal layer 154. The total die thickness T₁₅₀ may range from about 50 to about 150 micrometers. The recess 168 has a width W₁₆₈. As illustrated in the partial cross section, a width of the recess W₁₆₈, and, in this implementation, a width W₁₆₆ of overhang 166 is the difference between a width W₁₆₀ of the top surface 160 and a width W₁₆₂ of the bottom surface 162. As a result, during die attach, epoxy is able to occupy a volume of recess 168 in bottom region 172 of die 150 which reduces or prevents epoxy from moving up sidewall 164 onto top surface 160. Thus, sidewall 164 and recess 168 are configured to prevent epoxy from flowing onto top surface 160 of die 150. Consequently, the epoxy fillet height may be maintained below 75% of the total die thickness T₁₅₀ and preferably 50% or less of the total die thickness T₁₅₀.

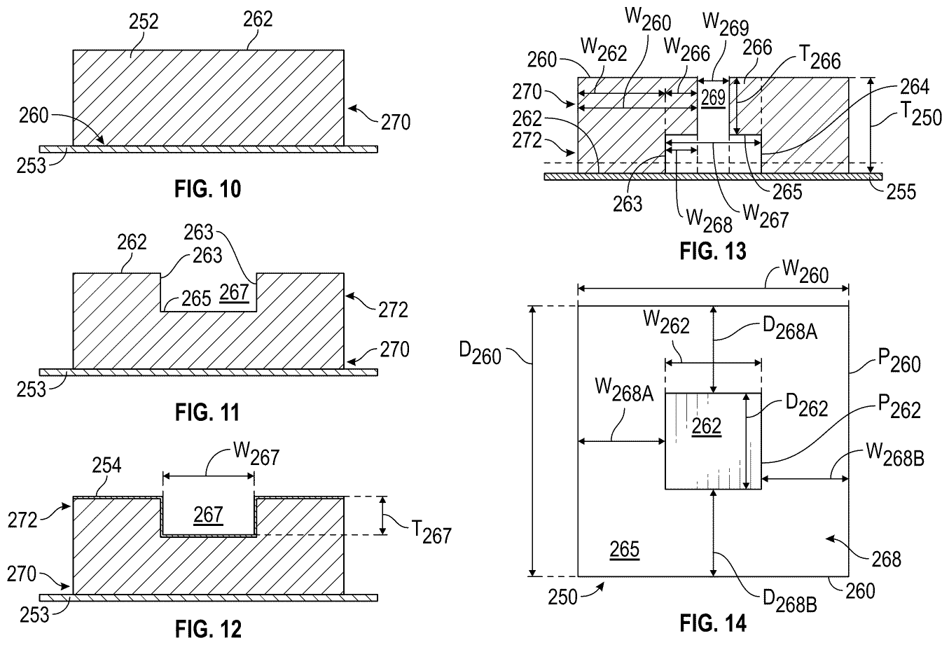

FIGS. 10 to 14 illustrate an implementation of a semiconductor substrate at various points during an implementation of a method of singulating a semiconductor die. FIG. 10 illustrates semiconductor substrate 252 which may be the same as or similar to any substrate type disclosed herein. In various implementations, the method implementation for singulating a plurality of die included in a substrate includes singulating a plurality of die included in the substrate 252 using saws through a mechanical dicing process.

Referring now to FIG. 10, substrate 252 is illustrated after being mounted top-down or active-side down onto cutting tape 253. Thus, a top/active surface 260 of top region 270 of substrate 252 contacts wafer tape 253. As illustrated in FIG. 11, the semiconductor substrate 252 is illustrated after formation of a recess 267 in a bottom region 272 of substrate 252. The recess 267 is defined by two lateral surfaces/sidewalls 263 and a horizontal surface 265. The recess may be formed by any suitable technique including, for example, cutting, mechanical cutting, laser cutting, and etching. In the implementation illustrated in FIG. 10, the recess 267 is formed by sawing the material of the semiconductor substrate 252 to form recess 267.

FIG. 12 illustrates the semiconductor substrate 252 following forming of an optional, additional layer 254 coupled to substrate 252. The layer 254 may be a metal or metal alloy deposited onto substrate 252 or any other additional layer type disclosed herein deposited using any method of depositing the material of the additional layer disclosed herein. The layer 254 is illustrated in FIG. 12 as being deposited onto bottom surface 262. As illustrated, recess 267 has a width W₂₆₇ and a thickness T₂₆₇ after additional metal layer 254 is formed onto substrate 252.

Referring to FIG. 13, a cross sectional side view of the substrate of FIG. 10 following singulation into semiconductor die 250 and after a wafer tape 253 to tape 255 transfer is illustrated. The method for singulating a plurality of die 250 included in the substrate 252 illustrated in FIG. 13 is sawing. However, in other implementations, the method may include singulating the plurality of die 250 using any other method of singulating disclosed in this document. As illustrated by FIGS. 12 and 13, the recess 267 width W₂₆₇ is intentionally wider than a kerf width W₂₆₉ of the saw blade, so the cut recess width W₂₆₇ is wider than the width 269 needed to singulate the die via mechanical cutting. In various implementations, the recess 267 is formed with a wider kerf width blade than the kerf width of the blade used to singulate the die 250 in the width 269. By cutting a wider area than needed for the singulating process, a recess 268 remains in each die 250 after singulating is performed as illustrated in FIG. 13.

In contrast to FIGS. 10 to 12 which show substrate 252 top side down, FIG. 13 shows substrate 252 and die 250 top side up as the semiconductor substrate has been removed from the cutting tape, flipped over, and mounted to cutting tape 255 again prior to the singulation process. As illustrated, die 250 includes a top surface 260, a bottom surface 262, and a sidewall 264 that extends between top surface 260 and bottom surface 262. Bottom surface 262 now contacts a tape 255 after the substrate 252 is demounted from wafer tape 253 and mounted to tape 255. Sidewall 264 includes horizontal surface 265 and lateral surface 263 created during the formation of recess 267 (see FIG. 11). A top portion of sidewall 264 and horizontal surface 265 define an overhang 266 adjacent recess 268. As previously described, the overhang 266 and recess 268 are formed due to the difference in width between the kerf width W₂₆₉ and the recess width W₂₆₇ during the singulation process. Since the kerf width W₂₆₉ is less than the recess width W₂₆₇, the resulting die 250 have a recess 268 in the bottom region 272 of die 250 and an overhang 266 in the top region 270 of die 250 adjacent recess 268.

As illustrated in FIG. 13, die 250 has a total die thickness T₂₅₀. A thickness T₂₆₆ of the overhang 266 is about 50% or more of the total die thickness T₂₅₀ and a thickness T₂₆₈ of the recess 268 is about 50% or less of the total die thickness T₂₅₀. The total die thickness T₂₅₀ includes the overhang thickness T₂₆₆, recess thickness T₂₆₈ and a thickness of metal layer 254 (not illustrated in FIG. 13 for simplicity of illustration). The total die thickness T₂₅₀ in various implementations may range from about 50 to about 150 micrometers. As illustrated in the partial cross section of FIG. 13, a width of the recess W₂₆₈, and, in this implementation, a width W₂₆₆ of overhang 266 are the difference between a width W₂₆₀ of the top surface 260 and a width W₂₆₂ of the bottom surface 262.

FIG. 14 illustrates a bottom view of die 250 following singulation and formation of recesses on all four sides of the die. While the formation of recesses on all four sides of the die is illustrated in FIG. 14, in various method implementations, recesses may be formed on only one side, two sides, three sides (where plasma or etch singulation is employed), four sides, or more sides of the die depending on the particular closed shape of the die. As illustrated in FIG. 14, a perimeter P₂₆₂ of bottom surface 262 is less than a perimeter P₂₆₀ of top surface 260 owing to the recess 268 in the bottom region 272 of die 250. The horizontal surface 265 of the recess is also illustrated in this bottom down view. While FIGS. 10-13 show the die in cross section and partial cross section, in various implementations, the recess 268 surrounds the bottom region 272 of the die. In various implementations, a width of top surface W₂₆₀ is equal to a width of recess W₂₆₈A, a width of bottom surface W₂₆₂ and a width of recess W₂₆₈B. The widths of recesses W₂₆₈A and W₂₆₈B may be the same or different from one another in various method implementations. In various implementations, a depth of the top surface D₂₆₀ is equal to a depth of recess D₂₆₈A, a depth of bottom surface D₂₆₂ and a depth of recess D₂₆₈B. However, in various method implementations, the depths of recesses D₂₆₈A and D₂₆₈B may be the same or different.

As previously discussed, during die attach, epoxy is able to occupy a volume of recess 268 in bottom region 272 which reduces or prevents excess epoxy from moving up sidewall 264 onto top surface 260. Thus, recess 268 and sidewall 264 are configured to prevent excess epoxy away flowing onto top surface 260 of die 250. Consequently, the epoxy fillet height may be maintained below 75% of the total die thickness T₂₅₀ and preferably 50% or less of the total die thickness T₂₅₀.

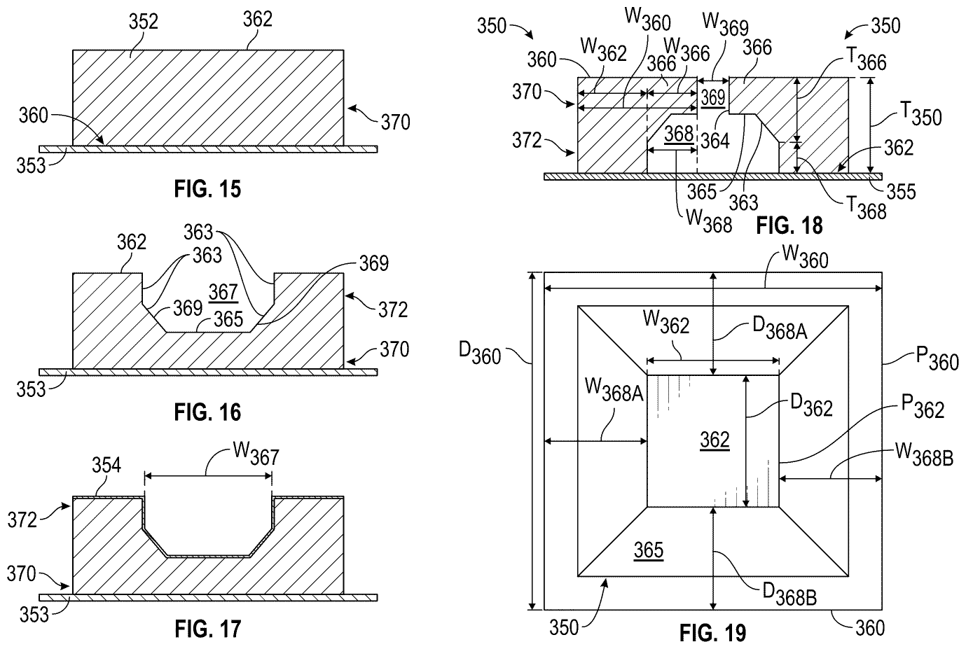

FIGS. 15-19 illustrate a semiconductor substrate at various points in an implementation of a method of singulating a semiconductor die. FIG. 15 illustrates semiconductor substrate 352. The substrate 352 may be any substrate type disclosed herein. In various method implementations, the method of singulating a plurality of die included in a substrate involves singulating using sawing.

Referring now to FIG. 15, substrate 352 is mounted top-down/active side down onto cutting tape 353. Thus, a top/active surface 360 of a top region 370 of substrate 352 contacts the wafer tape 353. As illustrated in FIG. 16, the semiconductor substrate 352 is illustrated following formation of a recess 367 in a bottom region 372 of substrate 352. The recess 367 is defined by lateral surfaces 363 and a horizontal surface 365. Lateral surfaces 363 include at least one beveled/angled edge 369. The recess 367 is formed using a beveled saw blade during a mechanical cutting process in the implementation illustrated in FIG. 17. However, in other implementations, the recess 367 may be formed by etching.

FIG. 17 illustrates an optional, additional layer 354 coupled to substrate 352. The layer 354 may be a metal or metal alloy or other material deposited onto substrate 352 using any deposition method disclosed herein that corresponds with the particular material of the additional layer. The layer 354 is illustrated deposited onto bottom surface 362. As illustrated, recess 367 has a width W₃₆₇ after metal layer 354 is added to substrate 352.

Referring to FIG. 18, a cross sectional side view of the substrate of FIG. 17 following singulation into semiconductor die 350 and after a wafer tape 353 to tape 355 transfer is illustrated. The method for singulating a plurality of die 350 included in the substrate 352 may include singulating the plurality of die 350 via mechanical cutting, sawing, dicing or the like. The method implementation utilized to singulate the semiconductor substrate illustrated in FIG. 18 is sawing. As illustrated in FIGS. 17 and 18, the recess width W₃₆₇ is intentionally wider than a kerf width W₃₆₉ of the saw blade used represented by width 369, so the cut recess width W₃₆₇ is wider than the width 369 needed to singulate the die via mechanical cutting. By cutting a wider area than needed for the singulating process, a beveled recess 368 remains in each die 350 after singulating is performed as illustrated in FIG. 18.

In contrast to FIGS. 15-17 which show substrate 352 top side down, FIG. 18 shows substrate 352 and die 350 top/active side up following demounting of the substrate 352 from the cutting tape 353 and mounting of the substrate 352 to cutting tape 355. As illustrated, die 350 includes top surface 360, bottom surface 362, and sidewall 364 that extends between top surface 360 and bottom surface 362. Bottom surface 362 contacts tape 355 after the substrate 352 is transferred from wafer tape 353 to tape 355. Sidewall 364 includes a portion of horizontal surface 365, lateral surface 363 and bevel/angle 369 created during the formation of recess 367 (FIG. 16). A top portion of sidewall 364, horizontal surface 365 and bevel/angled edge 369 define an overhang 366 adjacent recess 368. The overhang 366 and recess 368 are formed due to the difference in width between the kerf width W₃₆₉ and the recess width W₃₆₇ during the singulation process. Since the kerf width W₃₆₉ is less than the recess width W₃₆₇ the resulting die 350 have a recess 368 in the bottom region 372 of die 350 and an overhang 366 in the top region 370 of die 350 adjacent recess 368.

Die 350 has a total die thickness T₃₅₀. A maximum thickness T₃₆₆ of the overhang 366 is about 50% or more of the total die thickness T₃₅₀ and a maximum thickness T₃₆₈ of the recess 368 is about 50% or less of the total die thickness T₃₅₀. The total die thickness T₃₅₀ includes the overhang thickness T₃₆₆, recess thickness T₃₆₈ and a thickness T₃₅₄ of metal layer 354 (not shown in FIG. 18 for clarity). The total die thickness T₃₅₀ may range from about 50 to about 150 micrometers. TAs illustrated in the partial cross section of FIG. 18, a width of the recess W₃₆₈, and, in this implementation, a width W₃₆₆ of overhang 366 are the difference between a width W₃₆₀ of the top surface 360 and a width W₃₆₂ of the bottom surface 362.

FIG. 19 illustrates a bottom view of die 350. Again, while the die 350 has recesses on all four sides, various method implementations may form recesses on less than four sides or more that four sides depending on the number of sides the die has as previously described. As illustrated, a perimeter P₃₆₂ of bottom surface 362 is less than a perimeter P₃₆₀ of top surface 360 owing to the recess 368 in the bottom region 372 of die 350. The horizontal surface 365, bevel/angle 369 and bottom surface 362 are also illustrated. While FIGS. 15-18 show the substrate and dice in cross section and partial cross section, in various implementations, the recess 368 surrounds the bottom region 372 of die 350. In various implementations, a width of top surface W₃₆₀ is equal to a width of recess W_{368A}, a width of bottom surface W₃₆₂ and a width of recess W_{368B}. The widths of recesses W_{368A} and W_{368B} may be the same or different in various method implementations. In various implementations, a depth of the top surface D₃₆₀ is equal to a depth of recess D_{368A}, a depth of bottom surface D₃₆₂ and a depth of recess D_{368B}. The depths of recesses D_{368A} and D_{368B} may be the same or different in various method implementations.

During die attach, as previously discussed, epoxy is able to occupy the volume of recess 368 in bottom region 372 which reduces or prevents excess epoxy from flowing up sidewall 364 onto top surface 360. Thus, recess 368 and sidewall 364 are configured to prevent epoxy from flowing onto the top surface 360 of die 350. Consequently, the epoxy fillet height may be maintained below 75% of the total die thickness T₃₅₀ and preferably 50% or less of the total die thickness T₃₅₀.

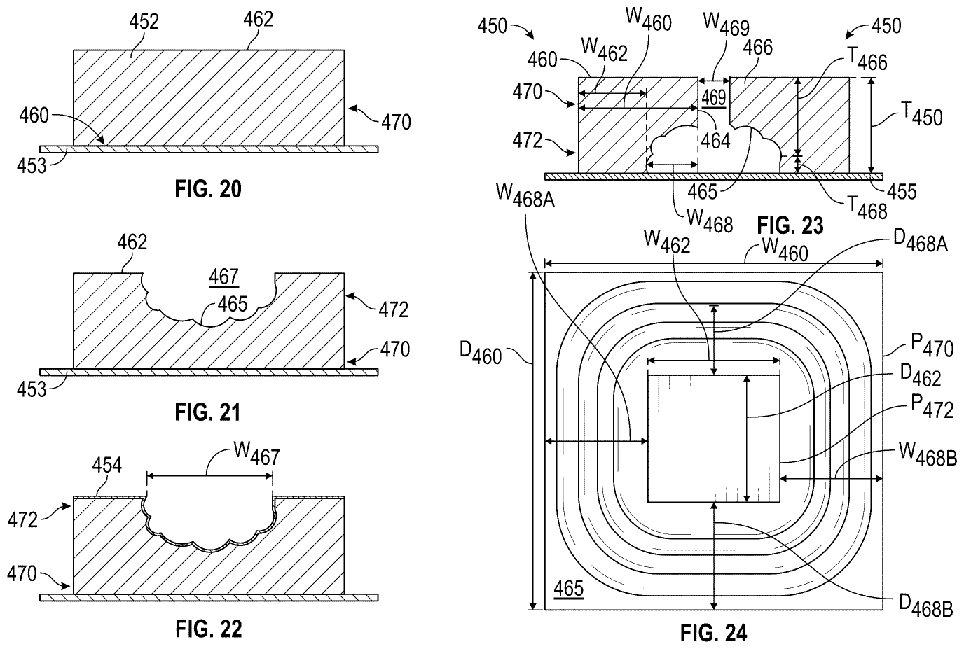

FIGS. 20-24 illustrate a semiconductor substrate at various points during an implementation of a method of singulating a semiconductor die. FIG. 20 illustrates a semiconductor substrate 452. The substrate 452 may be t any substrate type disclosed herein. In various method implementations, the method of singulating a plurality of die included in a substrate includes singulating using lasering or sawing.

Referring now to FIG. 20, substrate 452 is illustrated mounted top/active side-down onto cutting tape 453. Thus, a top/active surface 460 of a top region 470 of substrate 42 contacts cutting tape 453. As illustrated in FIG. 21, a recess 467 is formed in bottom region 472 of substrate 452 via laser cutting/scribing. The recess 467 is defined by a lasered surface 465 which is illustrated as containing the irregularities observed when lasering is used.

FIG. 22 illustrates an optional, additional layer 454 coupled to substrate 452. The layer 454 may be a metal, metal alloy or other material deposited onto substrate 452 using any deposition method disclosed herein that corresponds with the particular material type. The layer 454 is deposited onto bottom surface 462. As illustrated, recess 467 has a width W₄₆₇ after metal layer 454 is added to substrate 452.

Referring to FIG. 23, a cross sectional side view of the substrate of FIG. 22 following singulation at the recess 467 into semiconductor die 450 and after the substrate is demounted from a cutting tape 453 and mounted to cutting tape 455 is illustrated. The method for singulating a plurality of die 450 included in the substrate 452 includes singulating the plurality of die 450 via laser or sawing, in this method implementation. As illustrated by FIGS. 22 and 23, the recess width W₄₆₇ is intentionally wider than a blade kerf width W₄₆₉ of width 469, so the recess width W₄₆₇ is wider than the width needed to singulate the die. The recess 467 is formed with a laser that is has a wider cutting path that the width of the blade (or subsequent laser beam laser) used to singulate the die 450 in width 469. By cutting a wider area than needed for the singulating process, a recess 468 still remains in each die 450 after singulating is performed as illustrated in FIG. 23.

During singulation, a blade (or laser) cuts through width 469 including adjacent recess 467 to singulate substrate 452 into die 450. In contrast to FIGS. 20-22 which show substrate 452 top/active side down, FIG. 23 shows substrate 452 and die 450 top/active side up following the mounting and demounting process. As illustrated, die 450 includes top surface 460, bottom surface 462, and a sidewall 464 that extends between top surface 460 and bottom surface 462. Bottom surface 462 contacts cutting tape 455 after the substrate 452 is demounted from cutting tape 453 and mounted to cutting tape 455. Sidewall 464 includes lasered surface 465 created during the formation of recess 467 (FIG. 21) including the associated topography of the recess. A top portion of sidewall 464 and a portion of lasered surface 465 define an overhang 466 adjacent recess 468. The overhang 466 and recess 468 are formed due to the difference in width between the kerf width W₄₆₉ of the blade/laser cutting width and the recess width W₄₆₇ during the singulation process. Since the kerf width W₄₆₉ is less than the recess width W₄₆₇, the resulting die 450 have a recess 468 in the bottom region 472 of die 450 and an overhang 466 in the top region 470 of die 450 adjacent recess 468.

As illustrated, die 450 has a total die thickness T₄₅₀. A maximum thickness T₄₆₆ of the overhang 466 is about 50% or more of the total die thickness T₄₅₀ and a thickness T₄₆₈ of the recess 468 is about 50% or less of the total die thickness T₄₅₀. The total die thickness T₄₅₀ includes the overhang thickness T₄₆₆, recess thickness T₄₆₈, and a thickness T₄₅₄ of metal layer 454 not shown in FIG. 23 for clarity of illustration. The total die thickness T₄₅₀ may range from about 50 to about 150 micrometers. TAs illustrated in the partial cross section of FIG. 23, a width of the recess W₄₃₈, and, in this implementation, a width W₄₆₆ of overhang 466 are the difference between a width W₄₆₀ of the top surface 460 and a width W₄₆₂ of the bottom surface 462.

FIG. 24 illustrates a bottom view of die 450. As previously discussed, four recesses are illustrated in FIG. 24, but less or more recesses may be present in various method implementations as disclosed in this document. As illustrated, a perimeter P₄₆₂ of bottom surface 462 is less than a perimeter P₄₆₀ of top surface 460 owing to the recess 468 in the bottom region 472 of die 450. The lasered surface 465 and bottom surface 462 are illustrated including the topography created in the lasered surface 465. While FIGS. 20-23 show the substrate and die in cross section and partial cross section, in various implementations, recess 468 surrounds the bottom region 472 of die 450. In various implementations, a width of top surface W₄₆₀ is equal to a width of recess W₄₆₈A, a width of bottom surface W₄₆₂, and a width of recess W₄₆₈B. The widths of recesses W₄₆₈A and W₄₆₈B may be the same or different in various method implementations. In various implementations, a depth of the top surface D₄₆₀ is equal to a depth of recess D₄₆₈A, a depth of bottom surface D₄₆₂, and a depth of recess D₄₆₈B. The depths of recesses D₄₆₈A and D₄₆₈B may be the same or different in various method implementations. During die attach, epoxy occupies a volume of recess 468 in bottom region 472 which reduces or prevents excess epoxy from flowing up sidewall 464 onto top surface 460. Thus, recess 468 and sidewall 464 are able to prevent epoxy from flowing onto the top surface 460 of die 450. Consequently, the epoxy fillet height may be maintained below 75% of the total die thickness T₄₅₀ and preferably 50% or less of the total die thickness T₄₅₀.

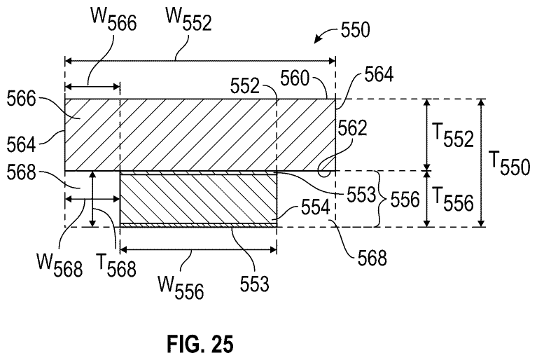

FIG. 25 is a cross sectional side view of an implementation of a semiconductor substrate having a thick metal layer deposited thereon. By “thick” is meant that the thickness of the metal layer is a substantial percentage of the thickness of the semiconductor substrate itself. Illustrated in FIG. 25 is semiconductor device 550 which includes a substrate 552 which may be any semiconductor substrate type disclosed herein that has a top surface 560, a bottom surface 562 and sidewalls 564. In various implementations, the thick metal layer may include a plurality of layers 556 are coupled to substrate 552. As illustrated, the plurality of layers 556 includes a first layer 553, a second layer 554 and a third layer 555. However, in various implementations, the plurality of layers 556 may include a single layer, more layers, or less layers than illustrated in FIG. 25. A first layer 553 is coupled to bottom surface 562 of substrate 552. The first layer 553 may include, for example, silicon nitride. A second layer 554 is coupled to first layer 553. The second layer 554 may be a metal layer and may be a copper layer, for example. A third layer 555 is coupled to second layer 554. The third layer 555 may be a metal layer and may be a silver layer in some implementations.

As illustrated, the substrate 552 has a width W₅₅₂ that is greater than a width W₅₅₆ of the thick metal layer (plurality of layers 556). This difference in width creates an overhang 566 of substrate 552 above a recess 568 adjacent the plurality of layers 556. The overhang 566 has a width of having a width W₅₆₆. Die 550 has a total die thickness T₅₅₀. In various implementations, a thickness of the substrate T₅₅₂ corresponds to a thickness of the overhang 566 and is about 50% or more of the total die thickness T₅₅₀. In various implementations, a thickness of the plurality of layers T₅₅₆ corresponds to a thickness of the recess 568 and is about 50% or less of the total die thickness T₅₅₀. The total die thickness T₅₅₀ may range from about 50 to about 150 micrometers. The recess 568 has a width W₅₆₈. The width of the recess W₅₆₈, and, in this implementation, the width W₅₆₆ of overhang 566 are the difference between a width W₅₆₂ of the substrate 552 and a width W₅₅₆ of the plurality of layers 556. In various other implementations, semiconductor device 550 may be configured such that the thickness of the substrate 552 is different from a thickness of the overhang, for example, first layer 553 may be as wide as substrate 552 and thus be part of the overhang 566. In various other implementations, semiconductor device 550 may be configured such that the thickness of the plurality of layers 556 is different from a thickness of the recess 568, for example, first layer 553 may be as wide as substrate 552 and thus be part of the overhang 566 and not define the recess 568. During die attach, epoxy that is beneath die 550, for example on a packaging substrate, may fill the volume of recess 568 instead of extending up sidewalls 564 toward top surface 560. Thus, the substrate 552 and plurality of layers 556 are configured to prevent excess epoxy from flowing to the top surface 560 of die 550.

The thick metal may be formed using an electroplating or electroless plating process in various implementations into a patterned resist material or may be formed by applying a film or foil of metal to the semiconductor substrate and then patterning and etching the film or foil where the recesses are desired. In the various method implementations, the etching process may be any consistent with etching the material of the thick metal including wet or dry etching. The patterning processes used to form the openings for electroplating or electroless plating or etching openings for the film or foil may be any disclosed in this document.

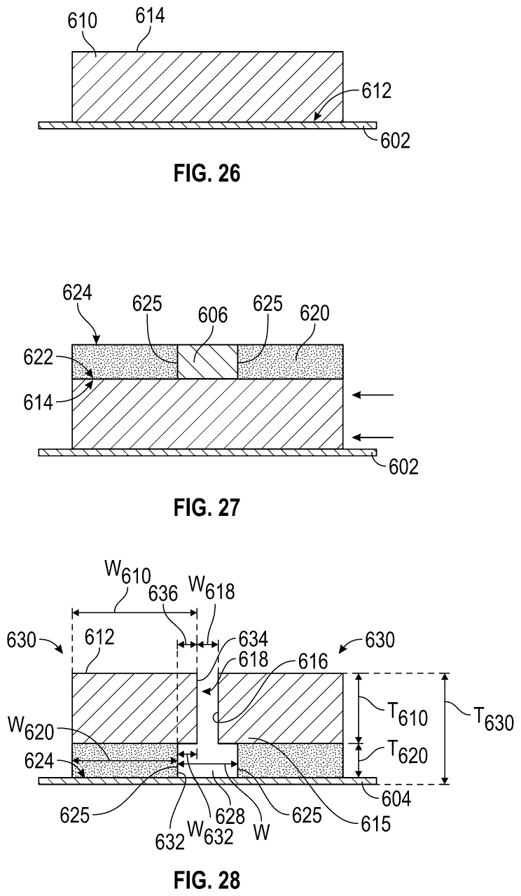

FIGS. 26-28 illustrate a semiconductor substrate at various points during an implementation of a method of forming a semiconductor die. FIG. 26 illustrates a semiconductor substrate 652which may be any substrate type disclosed herein. In various implementations, a method of singulating a plurality of die may includes singulating a plurality of die included in the substrate 652 using sawing, lasering, etching, or any other singulating process disclosed herein.

Referring now to FIG. 26, substrate 610 is mounted top/active side-down onto cutting tape 602. Substrate 610 has a top surface 612 contacting cutting tape 602 and a bottom surface 614 that is exposed.

As illustrated in FIG. 27, stencil 606 has been coupled with the bottom surface 614 and backside layer 620 a have been deposited on bottom surface 614 of substrate 610 through the openings in the stencil 606. A first or top surface 622 of backside layer 620 is now coupled to bottom surface 614 of substrate 610 and a second or bottom surface 624 of backside layer 620 is exposed. The stencil 606 abuts/directly contacts backside layer 620 on lateral surfaces 625 and the bottom surface 614 of substrate 610 to prevent any intrusion or application of the material of the backside layer underneath it. The backside layer 620 may be composed of, by non-limiting example, epoxy, glue, a die bonding material, a die attach material, any combination thereof or any other stable material that can be used to attach the substrate 610 to a package material. In various implementations, the backside layer 620 may include only carbon-containing materials. Depending on the material of the backside layer 620, curing or drying processes may be used to stabilize it for subsequent processing operations. In some implementations, the curing or drying processes may be carried out with the stencil in place; in other method implementations, the stencil is removed at the beginning or at a point during the curing or drying processes.

FIG. 28 illustrates die 630 following singulation of substrate 610. In contrast to FIGS. 26 and 27 which show substrate 610 top/active side down, FIG. 28 illustrates die 630 top/active side up following demounting of the substrate 610 from cutting tape 602 and mounting of the substrate 610 to cutting tape 604. After singulation is completed, a recess 626 is revealed formed using the thickness of the backside layer 620. The recess is defined by lateral surfaces 625 of the backside layer and bottom surface 614 of substrate 610. In various implementations, recess 626 has the same or similar dimensions as stencil 606 with any changes in shape and dimension that occur to the backside layer during the curing or drying processes.

Similarly to the other method implementations disclosed herein, during singulation, a blade/laser/water jet, etc. cuts through width 618 of substrate 610 in the area of recess 626 to singulate substrate 610 into die 630. As illustrated by FIG. 28, the recess width W₆₂₆ is intentionally wider than a kerf width W₆₁₈ of width 618, so the recess width W₆₂₆ is wider than the width needed to singulate the die. The recess 626 is formed with a wider stencil than the blade/laser cut, etc. used to singulate the die 630 in the width 618. By stenciling a wider recess 626 than needed for the singulating process, a resulting recess 632 remains formed by the backside layer and the die 630 after singulating is performed.

Each die 630 includes top surface 612 (top surface 612 of substrate 610), bottom surface 624 (bottom surface 624 of backside layer 620), and a sidewall 634 that extends between top surface 612 and bottom surface 624. Bottom surface 624 contacts cutting tape 604 after demounting from cutting tape 602 and mounting to cutting tape 604. Sidewall 634 includes a substrate sidewall 616, an exposed bottom face 615 of bottom surface 614 of substrate 610 and lateral surface 625 of backside layer 620. In various implementations, the shape of the stencil 606 can be constructed to create beveled or angled edges in the lateral surface 625 of the backside layer 620 as desired.

As illustrated in FIG. 28, substrate 610 overhangs backside layer 620 due to the formation of recess 626 created by stencil 606 thus forming an overhang 636. Substrate sidewall 616 and exposed bottom face 615 define overhang 636 of die 630. The overhang 636 is adjacent recess 632. The overhang 636 and recess 632 are created due to the difference in width between the width W₆₁₈ and the recess width W₆₂₆ during the singulation process. Since the width W₆₁₈ is less than the recess width W₆₂₆ the resulting die 630 have a recess 632 in the backside layer 620.

As illustrated in FIG. 28, die 630 has a total die thickness T₆₃₀. A thickness of the substrate T₆₁₀ corresponds to a thickness of the overhang 636 and is about 50% or more of the total die thickness T₆₃₀. A thickness of the backside layer T₆₂₀ corresponds to a thickness of the recess 632 and is about 50% or less of the total die thickness T₆₃₀. The total die thickness T₆₃₀ may range from about 50 to about 150 micrometers. T The width of the recess W₆₃₂, and, in this implementation, a width W₆₃₆ of overhang 636, are the difference between a width W₆₁₀ of the substrate 610 and a width W₆₂₀ of the backside layer 620.

During die attach, epoxy that is beneath die 630, for example on a packaging substrate, may fill the volume of recess 632 instead of flowing up sidewall 634 onto top surface 612. Thus, sidewall 634 including exposed bottom face 615 and recess 632 is structured to prevent epoxy from flowing onto top surface 612 of die 630 during die attach. Consequently, the epoxy fillet height may be maintained below 75% of the total die thickness T₆₃₀ and preferably 50% or less of the total die thickness T₆₃₀.

The semiconductor devices and methods disclosed herein and various implementations thereof may reduce the size of semiconductor packages and may allow glue to be used in thinner packages subsequently reducing costs associated with alternative adhesives and attachment mechanisms. Reliability of packages may be improved because glue is more reliable and has better thermal and electrical performance. Furthermore, manufacturing rejects related to fillet height issues as die become thinner may be reduced.

The semiconductor devices and methods disclosed herein may be used in power devices, automotive products, and electronics products, for example.

In places where the description above refers to particular implementations of semiconductor devices and methods of manufacturing thereof and related methods and implementing components, sub-components, methods and sub-methods, it should be readily apparent that a number of modifications may be made without departing from the spirit thereof and that these implementations, implementing components, sub-components, methods and sub-methods may be applied to other semiconductor devices and methods of manufacturing thereof.

What is claimed is:

1. A semiconductor device comprising:
a first surface having a first perimeter;
a second surface opposite the first surface, the second surface having a second perimeter, the first perimeter being greater than the second perimeter;
a sidewall extending between the first surface and the second surface, the sidewall defining an overhang, a width of the overhang extending between the first perimeter and the second perimeter, a thickness of the overhang being less than a thickness of the semiconductor device, the overhang configured to keep epoxy away from the first side.

2. The semiconductor device of claim 1, wherein the sidewall is curved or rounded.

3. The semiconductor device of claim 1, wherein the sidewall is angular.

4. The semiconductor device of claim 1, wherein the sidewall includes a bevel.

5. The semiconductor device of claim 1, wherein the sidewall is mechanically cut or laser cut.

6. The semiconductor device of claim 1, wherein a thickness of the semiconductor device is between 50 microns to 150 microns.

7. The semiconductor device of claim 1, wherein the thickness of the overhang is 50% of the semiconductor device thickness.

8. A method of singulating a plurality of die from a semiconductor substrate, the method comprising:
cutting a recess into a bottom region of a die, the recess having a first width along a bottom surface of the die, the recess having at least one beveled edge; and
singulating the die at the recess using a kerf width of a second width, wherein the second width is smaller than the first width.

9. The method of singulating of claim 8, wherein the recess is configured to prevent epoxy flowing onto a top surface of die.

10. The method of singulating of claim 8, wherein a sidewall extends between a top surface of the die and a bottom surface of the die, the sidewall defining an overhang adjacent the recess, a thickness of the overhang being less than a thickness of the die, the overhang configured to prevent epoxy flow onto the top surface of the die.

11. The method of singulating of claim 10, wherein the thickness of the overhang is 50% of the thickness of the die.

12. The method of singulating of claim 8, wherein a thickness of the die is between 50 microns to 150 microns.

13. The method of singulating of claim 8, wherein the recess is mechanically cut.

14. A method of singulating a plurality of die from a semiconductor substrate, the method comprising:
forming a recess in a backside layer applied to a backside of a semiconductor substrate using a stencil, the recess having a first width along a first surface of the backside layer; and
forming a plurality of die by singulating the semiconductor substrate in the recess using a kerf width of a second width, wherein the second width is smaller than the first width.

15. The method of singulating of claim 14, wherein the first surface of the backside layer is adjacent to the backside of the semiconductor substrate.

16. The method of singulating of claim 14, wherein the backside layer comprises epoxy, glue, a die bonding material, or any combination thereof.

17. The method of singulating of claim 14, wherein the backside layer comprises only a carbon-containing material.

18. The method of singulating of claim 14, wherein a sidewall extends between the backside surface of the semiconductor substrate and the first surface of the backside layer and a face of the backside surface of the semiconductor substrate extends past the first surface of the backside layer.

19. The method of singulating of claim 18, wherein the second width is 50% of a thickness of the semiconductor device.

20. The method of singulating of claim 14, wherein a thickness of the semiconductor substrate is from 50 microns to 150 microns.
